(19) United States
(12) Patent Application Publication
(10) Pub. No.: US 2025/0149392 A1
(43) Pub. Date: May 8, 2025

(54) PACKAGE SUBSTRATE AND MANUFACTURING METHOD THEREOF

(71) Applicant: Unimicron Technology Corp., Taoyuan City (TW)

(72) Inventors: Chia Ching Wang, Taoyuan City (TW); Chien-Chou Chen, Hsinchu County (TW); Hsuan Ming Hsu, Hsinchu County (TW); Ho-Shing Lee, Taoyuan City (TW); Yunn-Tzu Yu, Taoyuan City (TW); Yao Yu Chiang, New Taipei City (TW); Po-Wei Chen, New Taipei City (TW); Wei-Ti Lin, Hsinchu County (TW); Wen Chi Chang, Taoyuan City (TW)

(73) Assignee: Unimicron Technology Corp., Taoyuan City (TW)

(21) Appl. No.: 18/395,755

(22) Filed: Dec. 26, 2023

(30) Foreign Application Priority Data
Nov. 8, 2023 (TW) 112142987

(51) Int. Cl. H01L 23/12; H01L 23/00; H01L 23/31; H01L 23/498

(52) U.S. Cl. CPC H01L 23/12; H01L 23/3121; H01L 23/49822; H01L 23/49827; H01L 24/08; H01L 24/32; H01L 2224/08225; H01L 2224/32225; H01L 2924/181

(57) ABSTRACT

A package substrate includes a core layer, at least one functional component, at least one spacer, a filler, a first and a second build-up structures. The core layer has at least one opening and multiple conductive through vias. The functional component is disposed in the openings. The spacer is disposed on the functional component. The filler is filled in the opening, covering the functional component and spacer, and completely filling the gap between the opening, the functional component and the spacer. The first build-up structure is disposed on a first surface of the core layer and a third surface of the filler, and electrically connected to the functional component and the conductive through vias. The second build-up structure is disposed on a second surface of the core layer and a fourth surface of the filler, contacts the spacer and electrically connected to the conductive through vias.

### CROSS-REFERENCE TO RELATED APPLICATION

This application claims the priority benefit of Taiwan application serial no. 112142987, filed on Nov. 8, 2023. The entirety of the above-mentioned patent application is hereby incorporated by reference herein and made a part of this specification.

### BACKGROUND

### Technical Field

The disclosure relates to a substrate structure and a manufacturing method thereof, and in particular, to a package substrate and a manufacturing method thereof.

### Related Art

As chip scaling approaches physical limits, the industry continues to improve chip functionality with advanced packaging for high-end applications such as servers and autonomous driving. Advanced packaging requires larger and thicker IC carriers to carry more active devices, passive devices, memory, and logic chips, etc., which brings more complex design and heat dissipation difficulties. Component embedded package substrate is one of the high-end IC carriers, in which active or passive devices are embedded in the IC carrier to reduce product size and improve functionality, but it can make the product stacking, manufacturing, and heat dissipation design of products more complex, and poor design and production may affect the functionality and reliability of the finished product. Passive embedded substrate is most common. In the existing technology, a core layer with a thickness similar to that of the integrated passive devices (IPD) is used, on which a groove is dug out through mechanical processing, and integrated passive devices are placed into the groove, and then a build-up structure is formed to complete the entire stacking.

In a case where the thickness of the integrated functional component is close to the depth of the groove, when subsequently making the build-up structure, the build-up material after being laminated only needs to fill the gap between the integrated functional components and the grooves, and the surface may also maintain flatness. However, such method limits the stacking design of the entire embedded package substrate, leads to poor heat dissipation, and easily results in warping due to the thin core layer. When there is a drop between the thickness of the integrated functional component and the depth of the groove, when subsequently making the build-up structure, the build-up material after being laminated not only needs to fill the gap between the integrated functional component and the groove, but also needs to fill the space created by the drop, which also poses a challenge to maintaining surface flatness. If the integrated functional component is placed in larger-sized groove, or there is a need to place multiple integrated functional components respectively in multiple grooves, because the amount of dielectric material in the build-up structure is fixed, during lamination, it may not be enough to completely fill the space between the integrated functional component and the groove caused by the drop described above, and gap between the two. Further, the thickness of the dielectric layer of the build-up structure may become too thin, or the integrated functional components may be displaced or skewed (i.e. move upward in the Z direction in addition to moving in the X and Y directions) when being fixed. Moreover, bubbles may appear in the groove of the core layer because the build-up material is not completely filled, thereby affecting the heat dissipation efficiency of the embedded package substrate, and it is also easy to cause popcorn during high-temperature processes.

### SUMMARY

The disclosure provides a package substrate, which may have better heat dissipation effect and better structural reliability.

The disclosure further provides a manufacturing method of package substrate, which is used to manufacture the above-mentioned package substrate.

The package substrate according to the disclosure includes a core layer, at least one functional component, at least one spacer, a filler, a first build-up structure, and a second build-up structure. The core layer has a first surface and a second surface opposite each other, and at least one opening and a plurality of conductive through vias connecting the first surface and the second surface. At least one functional component is disposed in the at least one opening of the core layer, in which the at least one opening exposes at least one action surface of the at least one functional component. At least one spacer is disposed on the at least one functional component and has at least one top surface relatively away from the at least one functional component. The filler is filled in the at least one opening and has a third surface and a fourth surface opposite each other. The filler covers the at least one functional component and the at least one spacer and completely fills a gap between the at least one opening, the at least one functional component, and the at least one spacer. The third surface exposes the at least one action surface of the at least one functional component, and the fourth surface exposes the at least one top surface of at least one spacer. A first build-up structure is disposed on the first surface of the core layer and the third surface of the filler, and is electrically connected to the at least one functional component and the conductive through vias. A second build-up structure is disposed on the second surface of the core layer and the fourth surface of the filler, contacts the at least one top surface of the at least one spacer, and is electrically connected to the conductive through vias.

In one embodiment of the disclosure, there is a first height difference between the third surface of the filler and the first surface of the core layer, and there is a second height difference between the fourth surface of the filler and the second surface of the core layer.

In one embodiment of the disclosure, an orthographic projection of the at least one spacer on the at least one functional component is smaller than the at least one functional component.

In one embodiment of the disclosure, when viewed in cross section, a shape of a shape of the at least one spacer includes a rectangle, a trapezoid, or an inverted trapezoid, but is not limited thereto.

In one embodiment of the disclosure, the core layer has a first thickness, the at least one functional component has at least one second thickness, and a difference between the first thickness and the at least one second thickness is at least more than 100 microns.

In one embodiment of the disclosure, the at least one functional component is separated from an inner wall of the at least one opening by at least one spacing, and the at least one spacing is at least more than 20 microns.

In one embodiment of the disclosure, the at least one spacer includes at least one thermal interface material.

In one embodiment of the disclosure, the at least one spacer includes at least one first spacer and at least one second spacer, and the at least one first spacer is located between the at least one functional component and the at least one second spacer.

The manufacturing method of package substrate according to the disclosure includes the following steps. A core layer having at least one opening and a plurality of conductive through vias is provided, in which the core layer has a first surface and a second surface opposite each other. At least one functional component is disposed in the at least one opening of the core layer. At least one spacer is disposed on the at least one functional component. A filler is filled in the at least one opening. The filler covers the at least one functional component and the at least one spacer and completely fills a gap between at least one opening, at least one functional component, and at least one spacer. A third surface of the filler exposes at least one action surface of the at least one functional component, and a fourth surface of the filler exposes at least one top surface of the at least one spacer. A first build-up structure is formed on the first surface of the core layer and the third surface of the filler. The first build-up structure is electrically connected to the at least one functional component and the conductive through vias. A second build-up structure is formed on the second surface of the core layer and the fourth surface of the filler. The second build-up structure contacts the at least one top surface of the at least one spacer and is electrically connected to the conductive through vias.

In one embodiment of the disclosure, before disposing the at least one spacer on the at least one functional component, the filler is filled in the at least one opening, and a drilling process is performed on the filler to form at least one cavity that exposes part of the at least one functional component. The at least one spacer is disposed in the at least one cavity and directly contacts the at least one functional component.

In one embodiment of the disclosure, after disposing the at least one spacer on the at least one functional component, filler is filled in the at least one opening.

In one embodiment of the disclosure, the core layer has a first thickness, the at least one functional component has at least one second thickness, and a difference between the first thickness and the second thickness is at least more than 100 microns.

In one embodiment of the disclosure, the at least one spacer includes at least one thermal interface material.

In one embodiment of the disclosure, the at least one spacer includes at least one first spacer and at least one second spacer, and the at least one first spacer is located between the at least one functional component and the at least one second spacer.

Based on the above, in the design of the package substrate according to the disclosure, the functional component is disposed in the opening of the core layer, and the spacer is disposed on the functional component. The filler covers the functional component and the spacer and completely fills a gap between the opening, the functional component, and the spacer. That is, the functional component and the spacer are disposed in the opening of the core layer to reduce the step difference between the functional component and the core layer through the arrangement of the spacer. Since the filler completely fills a gap between the opening and the component, no bubbles will be generated, which allows the package substrate to have better structural reliability.

In order to make the above-mentioned features and advantages of the disclosure more obvious and easy to understand, embodiments are given below and described in detail with reference to the accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1G are schematic cross-sectional views of a manufacturing method of package substrate according to an embodiment of the disclosure.

FIG. 2A to FIG. 2E are partial cross-sectional schematic views of a manufacturing method of package substrate according to another embodiment of the disclosure.

FIG. 3A to FIG. 3D are partial cross-sectional schematic views of a manufacturing method of package substrate according to another embodiment of the disclosure.

FIG. 4 is a schematic cross-sectional view of a package substrate according to an embodiment of the disclosure.

### DESCRIPTION OF THE EMBODIMENTS

Reference will now be made in detail to the exemplary embodiments of the disclosure, examples of which are illustrated in the accompanying drawings. Wherever possible, the same reference numbers are used in the drawings and the description to refer to the same or like parts.

The embodiments of the disclosure may be understood together with the drawings, and the drawings of the disclosure are also regarded as part of the disclosure description. It is to be understood that the drawings of the disclosure are not drawn to scale and, in fact, the dimensions of elements may be arbitrarily exaggerated or reduced in order to clearly illustrate the features of the disclosure.

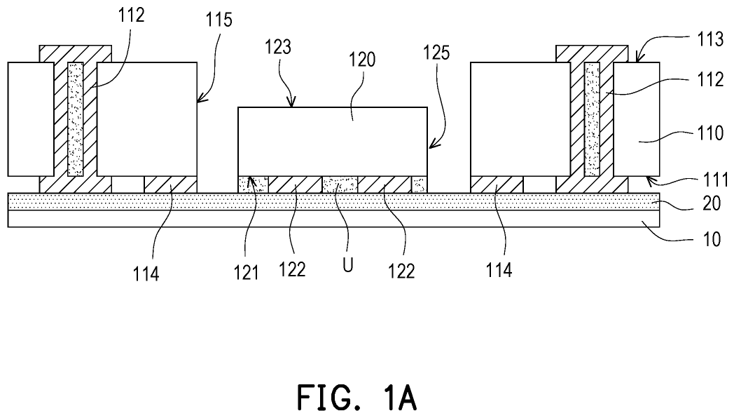

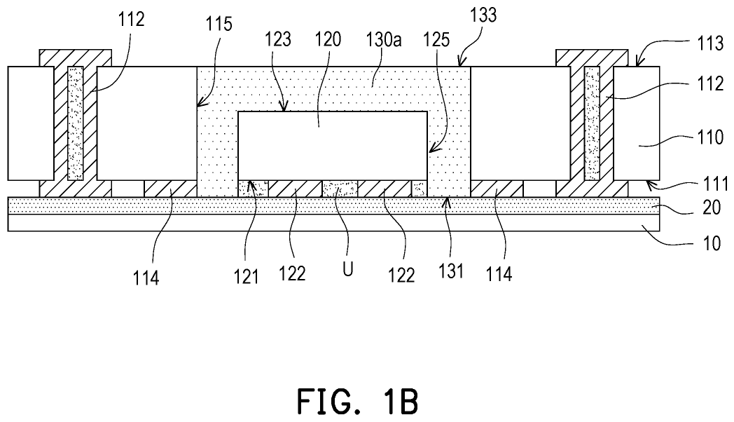

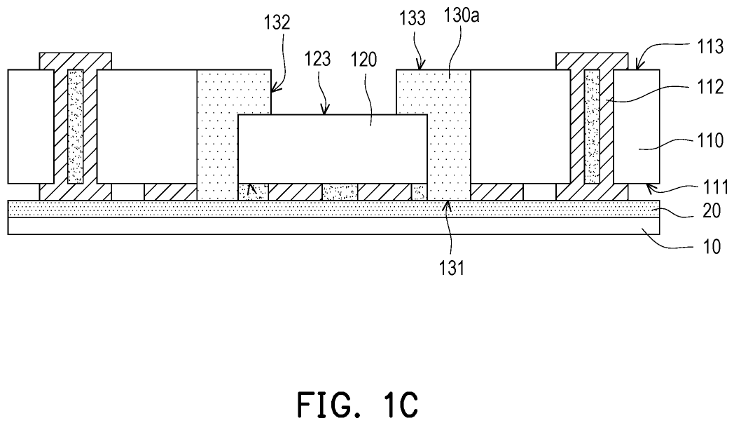

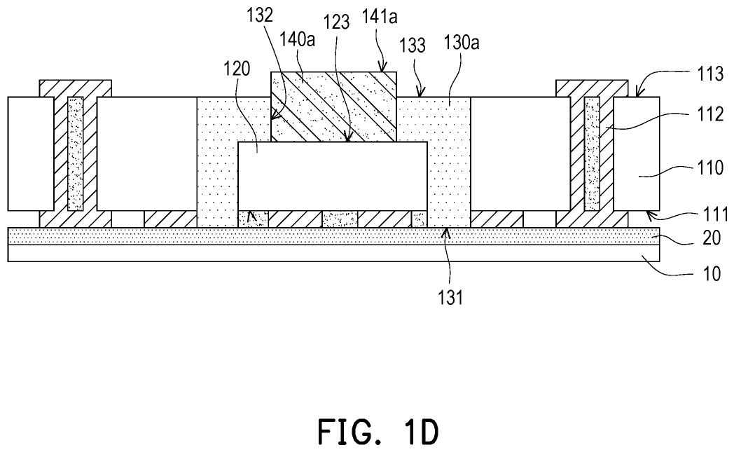

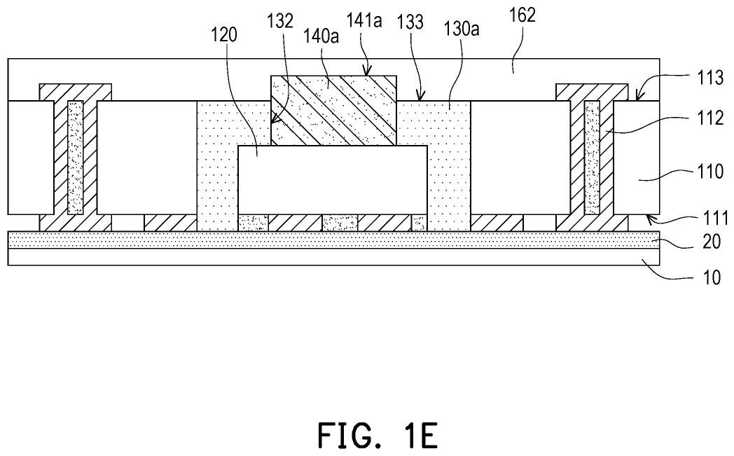

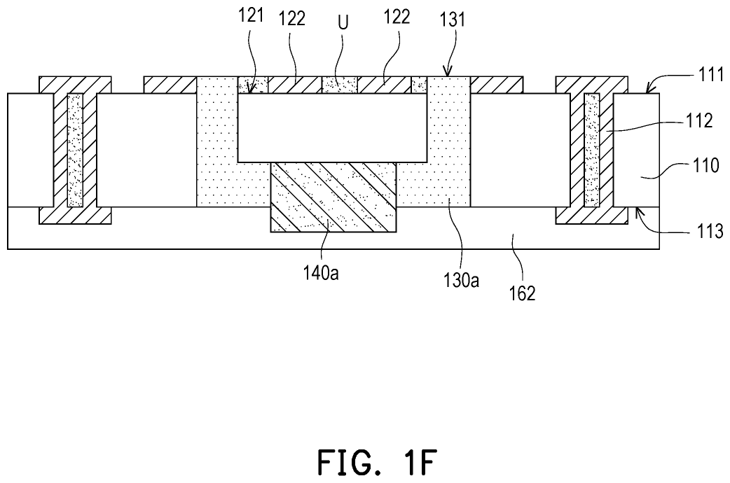

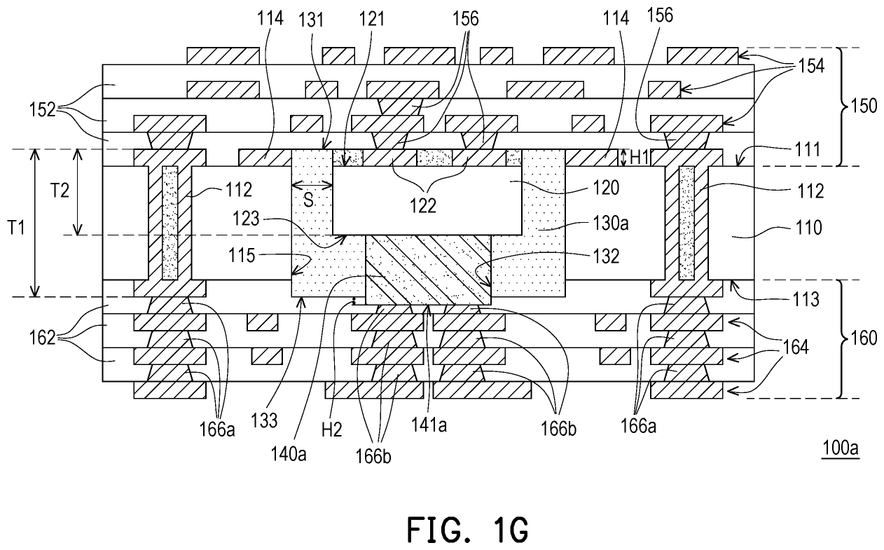

FIG. 1A to FIG. 1G are schematic cross-sectional views of a manufacturing method of package substrate according to an embodiment of the disclosure. First, please refer to FIG. 1A. According to the manufacturing method of package substrate of this embodiment, a core layer 110 having at least one opening (an opening 115 is schematically shown) and multiple conductive through vias (two conductive through vias 112 are schematically shown) is provided. In detail, first, the core layer 110 is provided. The core layer 110 has a first surface 111 and a second surface 113 opposite each other, the conductive through vias 112 penetrating the core layer 110 and connecting the first surface 111 and the second surface 113, and multiple wirings 114 disposed on the first surface 111. Next, a drilling process is performed on the core layer 110, such as mechanical drilling, molding, laser drilling, or stamping, to form the opening 115, wherein the conductive through vias 112 are arranged around the opening 115. Then, the core layer 110 having the opening 115 is disposed on a supporting film 10. The core layer 110 is temporarily fixed on the supporting film 10 through an adhesion layer 20 on the supporting film 10. The adhesion layer 20 may be, for example, double-sided tape, but is not limited thereto. Here, the core layer 110 may be, for example, a copper foil core layer, a BT resin core layer, a plastic core layer, a ceramic core layer, or other appropriate core layers, and is not limited thereto.

Next, please refer to FIG. 1A again. At least one functional component (a functional component 120 is schematically shown) is disposed in the opening 115 of the core layer 110. The functional component 120 has an action surface 121 and a back surface 123 opposite each other, a surrounding surface 125 connecting the action surface 121 and the back surface 123, and multiple contact pads 122 disposed on the action surface 121. The contact pads 122 directly contact the adhesion layer 20 such that the functional component 120 is fixed on the supporting film 10 and located in the opening 115 of the core layer 110. It should be noted that the action surface 121 is the surface on which the contact pads 122 are disposed, and may be regarded as an active surface. In one embodiment, a primer U may be selectively formed between the functional component 120 and the adhesion layer 20, wherein the primer U covers the contact pads 122. Here, the functional component 120 may be, for example, an integrated passive device (IPD). The size (e.g. thickness) of the core layer 110 is larger than the size (e.g. thickness) of the functional component 120, so there is a height difference between the back surface 123 of the functional component 120 and the second surface 113 of the core layer 110.

Next, please refer to FIG. 1B. A filler 130a is filled in the opening 115 of the core layer 110, wherein the filler 130a covers the back surface 123 and the surrounding surface 125 of the functional component 120. The filler 130a has a third surface 131 and a fourth surface 133 opposite each other. The third surface 131 directly contacts the adhesion layer 20, and the fourth surface 133 may be flush with the second surface 113 of the core layer 110, for example. The filler 130a is a filling material that is able to completely fill the gap (such as ink, paste, or powder), and is filled in the opening 115 by injet printing, screen printing, stencil printing, spray, dispensing, or deposition for example, and solidified. The height of the filler 130a may be equal to, slightly lower than, or slightly higher than the second surface 113 of the core layer 110, as long as the flatness and product characteristics during the subsequent build-up are not affected.

In one embodiment, the glass transition temperature (Tg) of the filler 130a is higher than 150° C., and the higher the better. The thermal expansion coefficient (α1-CTE) of the filler 130a below the glass transition temperature is less than 50, and the thermal expansion coefficient (α2-CTE) above the glass transition temperature is less than 150. The water absorption rate of the filler 130a is less than 1%. The viscosity of the filler 130a is less than 50,000 cP, and the lower the better. In one embodiment, the filler 130a may be SANEI's UCP series, wherein during pre-curing, the viscosity of the ink will be greatly reduced to less than 1000 cP for exhaust and gap filling, thereby avoiding gap caused by pasting that may cause popcorn in the subsequent reliability test.

Next, please refer to FIG. 1C. A drilling process is performed on the filler 130a, such

as laser ablation, or routing plus laser ablation, so as to form at least one cavity (a cavity 132 is schematically shown) that exposes part of the functional component 120. The cavity 132 extends from the fourth surface 133 of the filler 130a toward the third surface 131 to a part of the back surface 123 exposing the functional component 120.

Next, please refer to FIG. 1D. At least one spacer (a spacer 140a is schematically shown) is disposed on the functional component 120. The spacer 140a is disposed in the cavity 132 of the filler 130a and directly contacts the back surface 123 of the functional component 120. The spacer 140a completely fills in the cavity 132 by pick & place, injet printing, screen printing, stencil printing, spray, dispensing, or deposition for example, and solidified. At this time, the filler 130a covers the functional component 120 and the spacer 140a, and the fourth surface 133 of the filler 130a exposes at least one top surface of the spacer 140a (a top surface 141a is schematically shown). The top surface 141a of the spacer 140a needs to be equal to (i.e. flush with) or higher than the second surface 113 of the core layer 110. Here, the spacer 140a is, for example, a thermal interface material, which may be in paste, sheet, gel, or tape form.

Next, please refer to FIG. 1E. A dielectric layer 162 is formed on the second surface 113 of the core layer 110, the fourth surface 133 of the filler 130a, and the top surface 141a of the spacer 140a. The dielectric layer 162 covers the second surface 113 of the core layer 110, the fourth surface 133 of the filler 130a, and the top surface 141a of the spacer 140a.

Then, please refer to FIG. 1E and Figure IF at the same time. After turning the supporting film 10 and the core layer 110 thereon upside down, the adhesion layer 20 and the supporting film 10 are removed to expose the first surface 111 of the core layer 110, the contact pads 122 of the functional component 120 located on the action surface 121, and the third surface 131 of the filler 130a.

Finally, please refer to FIG. 1G. A first build-up structure 150 is formed on the first surface 111 of the core layer 110 and the third surface 131 of the filler 130a. The first build-up structure 150 is electrically connected to the functional component 120 and the conductive through vias 112. A second build-up structure 160 is formed on the second surface 113 of the core layer 110 and the fourth surface 133 of the filler 130a. The second build-up structure 160 contacts the top surface 141a of the spacer 140a and is electrically connected to the conductive through vias 112.

In detail, the first build-up structure 150 includes at least one dielectric layer 152 (three layers of dielectric layers 152 are schematically shown), at least one wiring layer 154 (three wiring layers 154 are schematically shown), and at least one conductive blind hole 156 (multiple conductive blind holes 156 are schematically shown). The dielectric layer 152 closest to the core layer 110 covers the first surface 111 of the core layer 110, the third surface 131 of the filler 130a, the wirings 114 on the core layer 110, the contact pads 122 of the functional component 120, and one end of the conductive through vias 112. The wiring layer 154 closest to the core layer 110 is disposed on the dielectric layer 152 and is electrically connected to the contact pads 122 of the functional component 120 and the conductive through vias 112 through the conductive blind holes 156. Other dielectric layers 152 and wiring layers 154 are stacked alternately, and the wiring layers 154 are electrically connected through the conductive blind holes 156.

The second build-up structure 160 includes at least one dielectric layer 162 (three layers of dielectric layers 162 are schematically shown), at least one wiring layer 164 (three layers of wiring layers 164 are schematically shown), at least one conductive blind hole 166a (multiple conductive blind holes 166a are schematically shown), and at least one thermal blind hole 166b (multiple thermal blind holes 166b are schematically shown). The dielectric layer 162 closest to the core layer 110 covers the second surface 113 of the core layer 110, the fourth surface 133 of the filler 130a, the top surface 141a of the spacer 140a, and the other end of the conductive through vias 112. The wiring layer 164 closest to the core layer 110 is disposed on the dielectric layer 162 and is electrically connected to the conductive through vias 112 through the conductive blind holes 166a, and contacts the top surface 141a of the spacer 140a through the thermal blind holes 166b. Other dielectric layers 162 and wiring layers 164 are stacked alternately, and the wiring layers 164 are electrically connected through the conductive blind holes 166a. At this point, the manufacturing of a package substrate 100a has been completed.

In terms of structure, please refer to FIG. 1G again. The package substrate 100a

includes the core layer 110, the functional component 120, the filler 130a, the spacer 140a, the first build-up structure 150, and the second build-up structure 160. The core layer 110 has the first surface 111 and the second surface 113 opposite each other, and the opening 115 and the conductive through vias 112 connecting the first surface 111 and the second surface 113. The functional component 120 is disposed in the opening 115 of the core layer 110, and the opening 115 exposes the action surface 121 of the functional component 120. The spacer 140a is disposed on the functional component 120 and has the top surface 141a relatively away from the functional component 120. The filler 130a is filled in the opening 115 and has the third surface 131 and the fourth surface 133 opposite each other. The filler 130a covers the functional component 120 and the spacer 140a, and completely fills the gap between the opening 115, the functional component 120, and the spacer 140a. The third surface 131 of the filler 130a exposes the action surface 121 of the functional component 120, and the fourth surface 133 of the filler 130a exposes the top surface 141a of the spacer 140a. The first build-up structure 150 is disposed on the first surface 111 of the core layer 110 and the third surface 131 of the filler 130a, and is electrically connected to the functional component 120 and the conductive through vias 112. The second build-up structure 160 is disposed on the second surface 113 of the core layer 110 and the fourth surface 133 of the filler 130a, contacts the top surface 141a of the spacer 140a, and is electrically connected to the conductive through vias 112.

Further, in this embodiment, the core layer 110 has a first thickness T1, and the functional component 120 has a second thickness T2. The difference between the first thickness T1 and the second thickness T2 is at least more than 100 microns. That is, this embodiment adopts the core layer 110 which is thicker than the functional component 120, which has better rigidity, better support, and is not easy to bend. In particular, the functional component 120 is separated from the inner wall of the opening 115 by at least one spacing S. The spacing S is at least more than 20 microns, which may facilitate the arrangement of the functional component 120 in the opening 115, and the filling of the filler 130a in the gap between the opening 115, the functional component 120, and the spacer 140a. There may be a first height difference H1 between the third surface 131 of the filler 130a and the first surface 111 of the core layer 110, and there may be a second height difference H2 between the fourth surface 133 of the filler 130a and the second surface 113 of the core layer 110, but not limited thereto. In another embodiment, the third surface 131 of the filler 130a may be flush with or slightly lower than the first surface 111 of the core layer 110, and the fourth surface 133 of the filler 130a may be flush with or slightly lower than the second surface 113 of the core layer 110, as long as the flatness and product characteristics during the subsequent build-up are not affected. Moreover, the orthographic projection of the spacer 140a of this embodiment on the functional component 120 is smaller than the functional component 120. In cross section view, the shape of the spacer 140a is, for example, a rectangle, but is not limited thereto.

The functional component 120 of this embodiment is disposed in the opening 115 of the core layer 110, and the spacer 140a is disposed on the functional component 120, in which the filler 130a covers the functional component 120 and the spacer 140a, and completely fills the gap between the opening 115, the functional component 120, and the spacer 140a. That is, the functional component 120 and the spacer 140a are disposed in the opening 115 of the core layer 110, wherein the spacer 140a is a thermal interface material, such that heat from the functional component 120 may be dissipated through the spacer 140a, thus the package substrate 100a has better heat dissipation performance. Moreover, since the filler 130a completely fills a gap between the opening 115 and the component, no bubbles will be generated, which allows the package substrate 100a to have better structural reliability.

Other examples will be given below as illustrations. It should be noted here that the following embodiments follow the reference numbers and part of the content of the previous embodiments, where the same reference numbers are used to represent the same or similar elements, and descriptions of the same technical content are omitted. For descriptions of omitted parts, reference may be made to the embodiments described above and will not be repeated in the following embodiments.

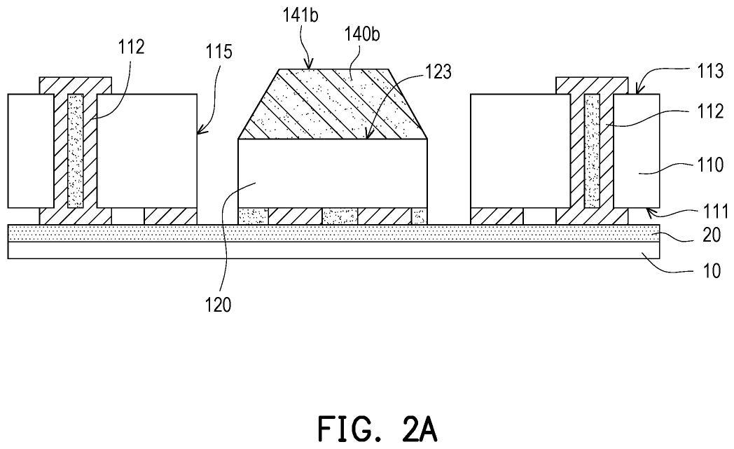

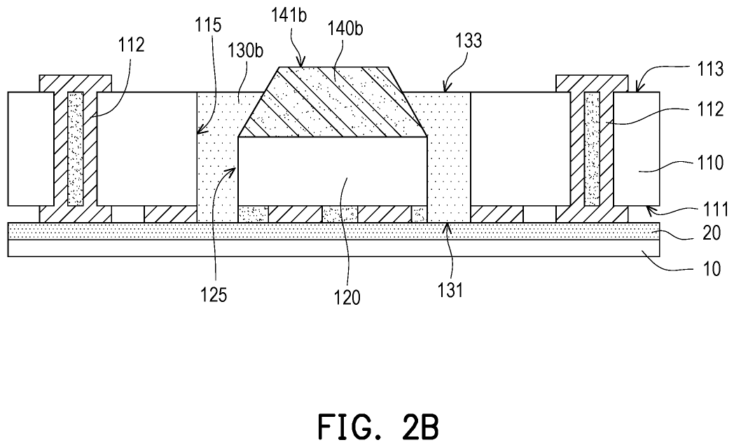

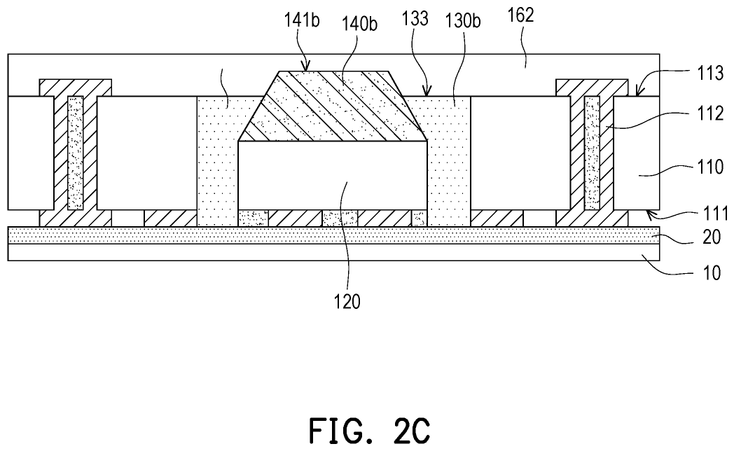

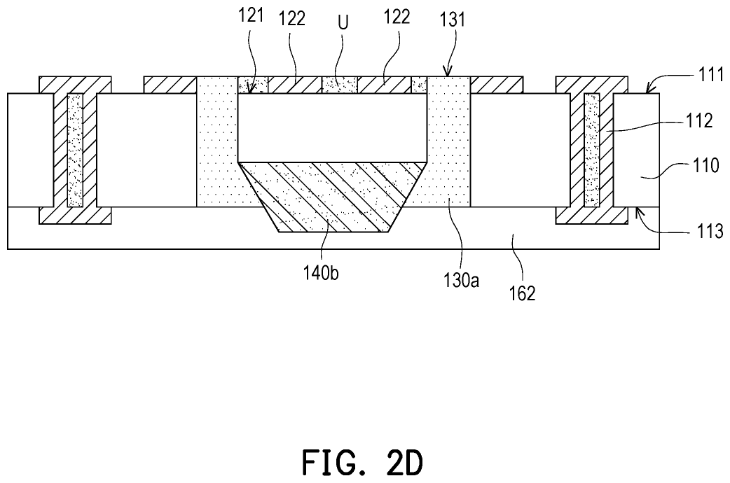

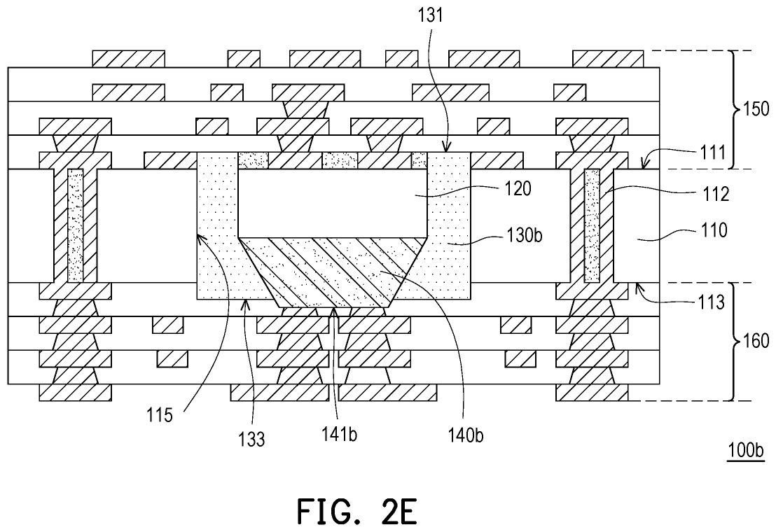

FIG. 2A to FIG. 2E are partial cross-sectional schematic views of a manufacturing method of package substrate according to another embodiment of the disclosure. Please refer to FIG. 1A and FIG. 2A at the same time. The manufacturing method of package substrate in this embodiment is similar to that of the package substrate described, and the main difference between the two is: in this embodiment, after the steps of FIG. 1A, i.e. after disposing the functional component in the opening 115 of the core layer 110 (please refer to FIG. 2A), a spacer 140b is disposed on the functional component 120. The spacer 140b is, for example, a thermal interface material, and the spacer 140b is directly formed on the functional component 120 by pick & place, injet printing, screen printing, stencil printing, spray, dispensing, or deposition for example, and solidified. At this time, the spacer 140b is located in the opening 115 and directly contacts the back surface 123 of the functional component 120, wherein a top surface 141b of the spacer 140b may be slightly higher than the second surface 113 of the core layer 110.

Next, please refer to FIG. 2B. A filler 130b is filled in the opening 115 of the core layer 110. The filler 130b covers the surrounding surface 125 of the functional component 120 and the spacer 140b, and exposes the top surface 141b of the spacer 140b. Here, the third surface 131 of the filler 130b directly contacts the adhesion layer 20, and the fourth surface 133 of the filler 130b may, for example, be flush with the second surface 113 of the core layer 110 and slightly lower than the top surface 141b of the spacer 140b. The filler 130b is a filling material that is able to completely fill the gap (such as ink, paste or powder), and is filled in the opening 115 by as injet printing, screen printing, stencil printing, spraying, dispensing or deposition, for example, and solidified. The height of the filler 130b may be equal to, slightly lower than, or slightly higher than the second surface 113 of the core layer 110, as long as the flatness and product characteristics during the subsequent build-up are not affected.

In one embodiment, the glass transition temperature (Tg) of the filler 130b is higher than 150° C., and the higher the better; the thermal expansion coefficient (α1-CTE) of the filler 130b below the glass transition temperature is less than 50, and the thermal expansion coefficient (α2-CTE) above the glass transition temperature is less than 150. The water absorption rate of the filler 130b is less than 1%. The viscosity of the filler 130b is less than 50,000 cP, and the lower the better. In one embodiment, the filler 130b may be SANEI's UCP series, wherein during pre-curing, the viscosity of the ink will be greatly reduced to less than 1000 cP for exhaust and gap filling, thereby avoiding gap caused by pasting that may cause popcorn in the subsequent reliability test.

Next, please refer to FIG. 2C. The dielectric layer 162 is formed on the second surface 113 of the core layer 110, the fourth surface 133 of the filler 130b, and the top surface 141b of the spacer 140b. The dielectric layer 162 covers the second surface 113 of the core layer 110, the fourth surface 133 of the filler 130b, and the top surface 141b of the spacer 140b.

Then, please refer to FIG. 2C and FIG. 2D at the same time. After turning the supporting film 10 and the core layer 110 thereon upside down, the adhesion layer 20 and the supporting film 10 are removed to expose the first surface 111 of the core layer 110, the contact pads 122 of the functional component 120 located on the action surface 121, and the third surface 131 of the filler 130b.

Finally, with the same steps as in FIG. 1G (please refer to FIG. 2E), the first build-up structure 150 is formed on the first surface 111 of the core layer 110 and the third surface 131 of the filler 130b, wherein the first build-up structure 150 is electrically connected to the functional component 120 and the conductive through vias 112. The second build-up structure 160 is formed on the second surface 113 of the core layer 110 and the fourth surface 133 of the filler 130b, wherein the second build-up structure 160 contacts the top surface 141b of the spacer 140b and is electrically connected to the conductive through vias 112. At this point, the manufacturing of a package substrate 100b has been completed.

In terms of structure, please refer to FIG. 1G and FIG. 2E at the same time. The package substrate 100b of this embodiment is similar to the above-mentioned package substrate 100a, and the main differences between the two is: in this embodiment, when viewed in cross section, the shape of the spacer 140b is, for example, an inverted trapezoid or a trapezoid, but is not limited thereto.

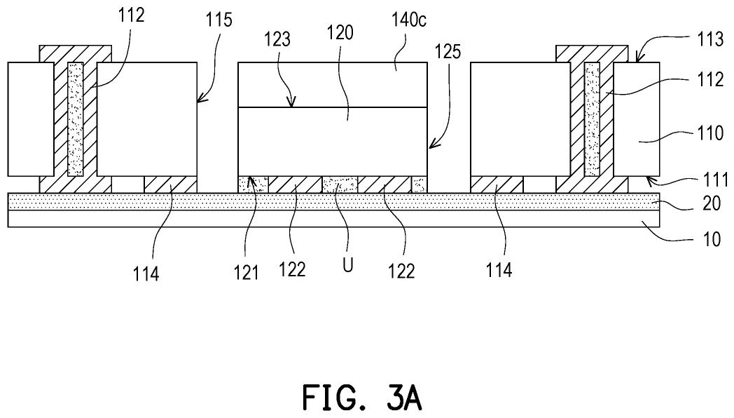

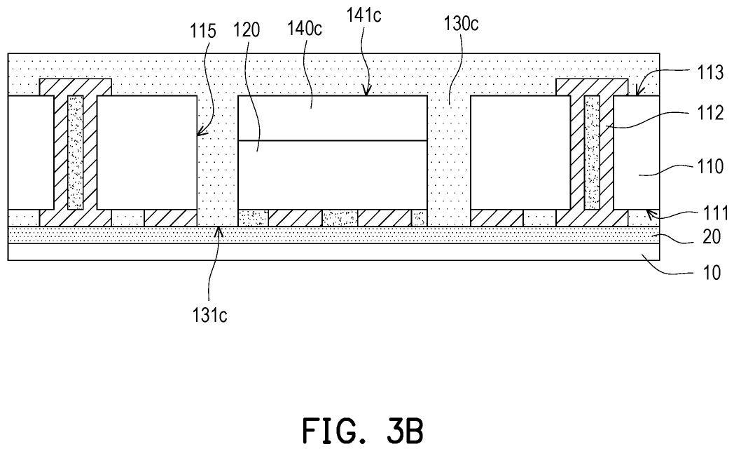

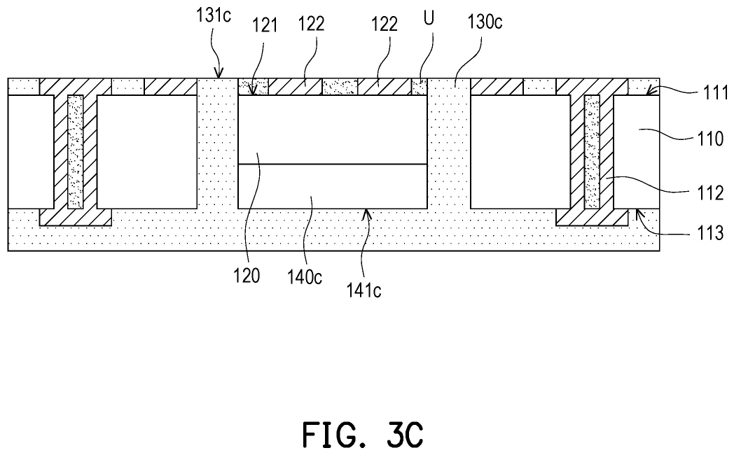

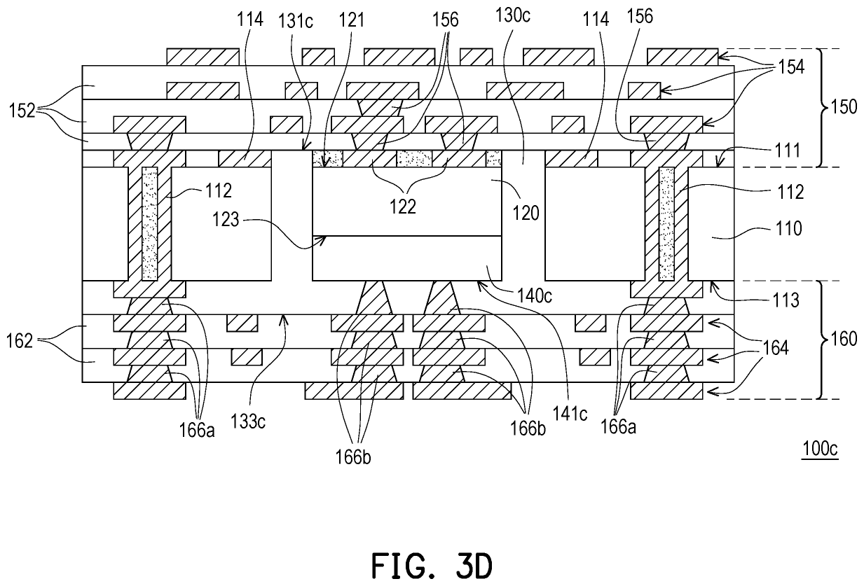

FIG. 3A to FIG. 3D are partial cross-sectional schematic views of a manufacturing method of package substrate according to another embodiment of the disclosure. Please refer to FIG. 1A and FIG. 3A at the same time. The manufacturing method of package substrate in this embodiment is similar to that of the package substrate mentioned above, and the main differences between the two is: in this embodiment, after the steps of FIG. 1A, that is, after disposing the functional components in the opening 115 of the core layer 110 (please refer to FIG. 3A), a spacer 140c is disposed on the back surface 123 of the functional component 120. The spacer 140c is, for example, a copper block, a tape, or other suitable raising material, which may be in solid, sheet, gel, or tape form, and is directly placed on the on the functional component 120b by pick & place, for example.

Next, please refer to FIG. 3B. A filler 130c is filled in the opening 115 of the core layer 110. The filler 130c covers the surrounding surface 125 of the functional component 120 and the spacer 140c, extends to be higher than the second surface 113 of the core layer 110, and covers a top surface 141c of the spacer 140c and the side of the conductive through vias 112 relatively away from the adhesion layer 20. At this time, a third surface 131c of the filler 130c directly contacts the adhesion layer 20 and completely fills a gap between the core layer 110 and the adhesion layer 20.

Then, please refer to FIG. 3B and FIG. 3C at the same time. After turning the supporting film 10 and the core layer 110 thereon upside down, the adhesion layer 20 and the supporting film 10 are removed to expose the side of the conductive through vias 112 relatively away from the adhesion layer 20, the contact pads 122 of the functional component 120 located on the action surface 121, and the primer U and the third surface 131c of the filler 130c.

Finally, please refer to FIG. 3D. The first build-up structure 150 is formed on the

first surface 111 of the core layer 110 and the third surface 131c of the filler 130c, in which the first build-up structure 150 is electrically connected to the functional component 120 and the conductive through vias 112. The second build-up structure 160 is formed on the second surface 113 of the core layer 110 and a fourth surface 133c of the filler 130c, wherein the second build-up structure 160 contacts the top surface 141c of the spacer 140c and is electrically connected to the conductive through vias 112. At this point, the manufacturing of a package substrate 100c has been completed.

In terms of structure, please refer to FIG. 1G and FIG. 3D at the same time. The package substrate 100c of this embodiment is similar to the package substrate 100a, and the main difference between the two is: in this embodiment, the spacer 140c may be a copper block, a tape, or other suitable raising material, but is not limited thereto.

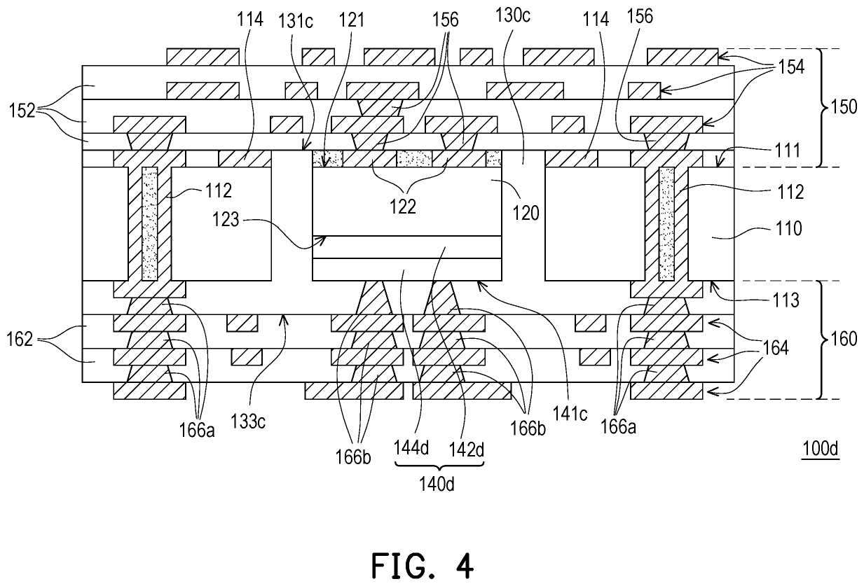

FIG. 4 is a schematic cross-sectional view of a package substrate according to an embodiment of the disclosure. Please refer to FIG. 3D and FIG. 4 at the same time. A package substrate 100d of this embodiment is similar to the package substrate 100c, and the main difference between the two is: in this embodiment, a spacer 140d includes a first spacer 142d and a second spacer 144d, wherein the first spacer 142d is located between the functional component 120 and the second spacer 144d. That is, in this embodiment, the spacer 140d are stacked to achieve an appropriate thickness.

It should be noted that in the above-mentioned embodiments, the package substrate 100a, the package substrate 100b, the package substrate 100c, and the package substrate 100d only schematically illustrate one functional component 120, but are not limited thereto. In practical applications, the package substrate 100a, the package substrate 100b, the package substrate 100c, and the package substrate 100d may include (embed) dozens to hundreds of functional components 120, which may be increased according to usage requirements.

To sum up, in the design of the package substrate according to the disclosure, the functional component is disposed in the opening of the core layer, and the spacer is disposed on the functional component. t. The filler covers the functional component and the spacer and completely fills a gap between the opening, the functional component, and the spacer. That is, the functional component and the spacer are disposed in the opening of the core layer to reduce the step difference between the functional component and the core layer through the arrangement of the spacer. Since the filler completely fills a gap between the opening and the component, no bubbles will be generated, which allows the package substrate to have better structural reliability.

It will be apparent to those skilled in the art that various modifications and variations may be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A package substrate, comprising:
a core layer, having a first surface and a second surface opposite each other, and at least one opening and a plurality of conductive through vias connecting the first surface and the second surface;
at least one functional component, disposed in the at least one opening of the core layer, wherein the at least one opening exposes at least one action surface of the at least one functional component;
at least one spacer, disposed on the at least one functional component and having at least one top surface relatively away from the at least one functional component;
a filler, filled in the at least one opening and having a third surface and a fourth surface opposite each other, wherein the filler covers the at least one functional component and the at least one spacer and completely fills a gap between the at least one opening, the at least one functional component, and the at least one spacer, the third surface exposes the at least one action surface of the at least one functional component, and the fourth surface exposes the at least one top surface of the at least one spacer;
a first build-up structure, disposed on the first surface of the core layer and the third surface of the filler and electrically connected to the at least one functional component and the conductive through vias; and
a second build-up structure, disposed on the second surface of the core layer and the fourth surface of the filler, contacting the at least one top surface of the at least one spacer, and electrically connected to the conductive through vias.

2. The package substrate according to claim 1, wherein there is a first height difference between the third surface of the filler and the first surface of the core layer, and there is a second height difference between the fourth surface of the filler and the second surface of the core layer.

3. The package substrate according to claim 1, wherein an orthographic projection of the at least one spacer on the at least one functional component is smaller than the at least one functional component.

4. The package substrate according to claim 3, wherein when viewed in cross section, a shape of the at least one spacer comprises a rectangle, a trapezoid, or an inverted trapezoid.

5. The package substrate according to claim 1, wherein the core layer has a first thickness, the at least one functional component has at least one second thickness, and a difference between the first thickness and the at least one second thickness is at least more than 100 microns.

6. The package substrate according to claim 1, wherein the at least one functional component is separated from an inner wall of the at least one opening by at least one spacing, and the at least one spacing is at least more than 20 microns.

7. The package substrate according to claim 1, wherein the at least one spacer comprises at least one thermal interface material.

8. The package substrate according to claim 1, wherein the at least one spacer comprises at least one first spacer and at least one second spacer, and the at least one first spacer is located between the at least one functional component and the at least one second spacer.

9. A manufacturing method of package substrate, comprising:
providing a core layer having at least one opening and a plurality of conductive through vias, wherein the core layer has a first surface and a second surface opposite each other;
disposing at least one functional component in the at least one opening of the core layer;
disposing at least one spacer on the at least one functional component;
filling a filler in the at least one opening, the filler coving the at least one functional component and the at least one spacer and completely filling a gap between the at least one opening, the at least one functional component, and the at least one spacer, wherein a third surface of the filler exposes at least one action surface of the at least one functional component, and a fourth surface of the filler exposes at least one top surface of the at least one spacer;
forming a first build-up structure on the first surface of the core layer and the third surface of the filler, wherein the first build-up structure is electrically connected to the at least one functional component and the conductive through vias; and
forming a second build-up structure on the second surface of the core layer and the fourth surface of the filler, wherein the second build-up structure contacts the at least one top surface of the at least one spacer and is electrically connected to the conductive through vias.

10. The manufacturing method of package substrate according to claim 9, wherein before disposing the at least one spacer on the at least one functional component, the filler is filled in the at least one opening, and a drilling process is performed on the filler to form at least one cavity exposing part of the at least one functional component, wherein the at least one spacer is disposed in the at least one cavity and directly contacts the at least one functional component.

11. The manufacturing method of package substrate according to claim 9, wherein after disposing the at least one spacer on the at least one functional component, the filler is filled in the at least one opening.

12. The manufacturing method of package substrate according to claim 9, wherein the core layer has a first thickness, the at least one functional component has at least one second thickness, and a difference between the first thickness and the at least one second thickness is at least more than 100 microns.

13. The manufacturing method of package substrate according to claim 9, wherein the at least one spacer comprises at least one thermal interface material.

14. The manufacturing method of package substrate according to claim 9, wherein the at least one spacer comprises at least one first spacer and at least one second spacer, and the at least first spacer is located between the at least one functional component and the at least one second spacer.
